(19) United States
(12) Patent Application Publication
(10) Pub. No.: US 2025/0241185 A1
(43) Pub. Date: Jul. 24, 2025

(54) DISPLAY PANEL, MANUFACTURING METHOD THEREOF, AND MOBILE TERMINAL

(71) Applicant: Wuhan China Star Optoelectronics Semiconductor Display Technologies Co., Ltd., Wuhan (CN)

(72) Inventor: Wenjun ZHOU, Wuhan (CN)

(21) Appl. No.: 17/637,538

(22) PCT Filed: Dec. 28, 2021
(86) PCT No.: PCT/CN2021/142081

§ 371 Date: Feb. 23, 2022

(30) Foreign Application Priority Data
Dec. 16, 2021 (CN) 202111547074.3

(51) Int. Cl. H10K 59/80

(52) U.S. Cl. CPC H10K 59/8792

(57) ABSTRACT

A display panel, a manufacturing method thereof, and a mobile terminal are provided and include: a substrate arranged from bottom to top, a light-emitting layer, and a color resistance layer, wherein the light-emitting layer includes a plurality of light-emitting parts, at least one light-emitting part is a first type of light-emitting part, the color resistance layer includes a plurality of color resistance parts corresponding to a plurality of light-emitting parts on a one-to-one correspondence, each color resistance part is arranged opposite to the corresponding light-emitting part, and in the plurality of color resistance parts, a first type of color resistance part arranged opposite to the first type of light-emitting part includes a shielding part for blocking light from passing through.

### FIELD OF INVENTION

The present disclosure relates to the field of display technology, especially the manufacture of display devices, in particular to a display panel, a manufacturing method thereof, and a mobile terminal.

### BACKGROUND OF INVENTION

Organic light-emitting diode (OLED) panel has the advantages of light and thin, wide viewing angle and power saving, and will become the mainstream of future development.

Wherein, the OLED panel manufactured with the depolarizer technology is made by providing a color resistance layer and a black matrix layer to replace the polarizer, and when performing the pixel repair, a common laser cannot penetrate the color resistance of a part of colors to remove the conductive material in a corresponding region, resulting in that a part of sub-pixels corresponding to the part of color resistance cannot be repaired, reducing the success rate of pixel repair.

Therefore, the success rate of pixel repair of the OLED panel manufactured by the depolarizer technology is low, and the improvement is urgently needed.

### SUMMARY OF INVENTION

### Technical Problem

An objective of the present disclosure is to provide a display panel, its manufacture method, and a display device, so as to solve the technical problem of a low success rate of pixel repair of an OLED panel manufactured with a depolarizer technology.

### Technical Solution

Embodiments of the present disclosure provide a display panel including:
a substrate;
a light-emitting layer located on the substrate, wherein the light-emitting layer includes a plurality of light-emitting parts, and at least one of the light-emitting parts is a first type of light-emitting part;
a color resistance layer located on a side of the light-emitting layer away from the substrate, the color resistance layer including a plurality of color resistance parts corresponding to a plurality of the light-emitting parts on a one-to-one basis, each of the color resistance parts being arranged opposite to a corresponding light-emitting part, and at least one of the color resistance parts being a first type of color resistance part arranged opposite to the first type of light-emitting part;
wherein the first type of color resistance part includes a shielding part that is configured to block light from passing through.

In an embodiment, the shielding part is located in a region of the corresponding the first type of color resistance part away from the light-emitting layer.

In an embodiment, the constituent material of the shielding part includes carbon.

In an embodiment, the display panel further includes:
a black matrix layer arranged on the same layer as the color resistance layer, wherein the black matrix layer includes a plurality of black matrix parts, an included angle between a side portion and a bottom portion of the black matrix part is an acute angle, and a color resistance part is filled between the two adjacent black matrix parts;
wherein each side portion of the shielding part is coplanar with an adjacent side portion of the adjacent color resistance part.

In an embodiment, the first type of light-emitting part includes an abnormal region, and the shielding part is disposed opposite to the abnormal region in the corresponding the first type of light-emitting part.

In an embodiment, the display panel further includes:
an anode layer located on a side of the light-emitting layer close to the substrate, wherein the anode layer includes a plurality of anode parts corresponding to a plurality of the light-emitting parts on a one-to-one basis;
a cathode layer located on a side of the light-emitting layer away from the substrate, wherein the cathode layer covers at least a side of the first type of light-emitting part away from the substrate.

In an embodiment, at least one of the light-emitting parts is a second type of light-emitting part, and the cathode layer is provided with at least one of openings arranged opposite to the second type of light-emitting part.

In an embodiment, a plurality of color resistance parts corresponding to a plurality of the light-emitting parts different in light-emitting colors on a one-to-one basis have a transmittance of more than 60% for light having a wavelength of more than 850 nm.

In an embodiment, the display panel further includes:
a touch control layer located on a side of the color resistance layer close to the light-emitting layer, wherein the touch control layer includes a plurality of touch control electrodes, and the touch control electrodes are located between the two adjacent light-emitting parts.

Embodiments of the present disclosure provide a mobile terminal including a terminal main body part and a display panel as described in any one of the above; the terminal main body part and the display panel are integrated.

Embodiments of the present disclosure provide a method of manufacturing of a display panel, including following steps:
providing a substrate;
forming a light-emitting layer on the substrate, wherein the light-emitting layer includes a plurality of light-emitting parts, and at least one of the light-emitting parts is the first type of light-emitting part; and
forming a color resistance layer on a side of the light-emitting layer away from the substrate, wherein the color resistance layer includes a plurality of color resistance parts corresponding to a plurality of the light-emitting parts on a one-to-one basis, each of the color resistance parts is arranged opposite to a corresponding light-emitting part, at least one of the color resistance parts is a first type of color resistance part arranged opposite to the first type of light-emitting part, and the first type of color resistance part includes a shielding part that is configured to block light from passing through;
wherein the step of forming the first type of color resistance part includes following steps:
forming a first type of color resistance block on a side of the first type of light-emitting part away from the substrate; and
processing the first type of color resistance block by a laser from a side of the first type of color resistance block away from the substrate to form the shielding part within the first type of color resistance block.

In an embodiment, before step of forming a color resistance layer on a side of the light-emitting layer away from the substrate, the method includes following steps:
forming a cathode layer, a touch control layer located on the cathode layer, and a plurality of black matrix parts located on the touch control layer successively, and the touch control layer including a plurality of touch control electrodes; wherein,
after step of forming a color resistance layer on a side of the light-emitting layer away from the substrate, the method includes:
forming a planarization layer on a side of the color resistance layer and the plurality of black matrix parts away from the substrate.

### Beneficial Effects

The present disclosure provides a display panel, its method for manufacturing, and a mobile terminal, wherein the display panel includes: a substrate; a light-emitting layer located on the substrate, wherein the light-emitting layer includes a plurality of light-emitting parts, and at least one of the light-emitting parts is the first type of light-emitting part; and a color resistance layer located on a side of the light-emitting layer away from the substrate, the color resistance layer including a plurality of color resistance parts corresponding to a plurality of the light-emitting parts on a one-to-one basis, each of the color resistance parts being arranged opposite to a corresponding light-emitting part, and at least one of the color resistance parts being the first type of color resistance part arranged opposite to a first type of light-emitting part; wherein the first type of color resistance part includes a shielding part that is configured to block light from passing through. Wherein, in the present disclosure, the first type of color resistance part is arranged to include a shielding part for blocking light from passing through so as to achieve the function of blocking light emitted by the first type of color resistance part from passing through avoiding the use of a laser to penetrate the color resistance part to eliminate bright spots, and improves the success rate of pixel repair.

### BRIEF DESCRIPTION OF DRAWINGS

The present disclosure is further described with reference to the accompanying drawings. It should be noted that the accompanying drawings in the following description are merely some embodiments of the present disclosure, and a person skilled in the art may still derive other drawings from these accompanying drawings without creative efforts.

FIG. 1 is the schematic diagram of the cross section of the first type of display panel provided in the embodiment of the present disclosure.

FIG. 2 is the schematic diagram of the cross section of the second type of display panel provided in the embodiment of the present disclosure.

FIG. 3 is the schematic diagram of the cross section of the third type of display panel provided in the embodiment of the present disclosure.

FIG. 4 is the distribution graph for the rate of penetration of the color resistance parts in different colors to light provided in the embodiment of the present disclosure.

FIG. 5 is the flowchart illustrating the method of manufacturing of a display panel provided in the embodiment of the present disclosure.

FIG. 6 is a schematic diagram illustrating a scenario of the method of manufacturing of the display panel provided in the embodiment of the present disclosure.

FIG. 7 is a schematic diagram illustrating another scenario of the method the manufacturing of the display panel provided in the embodiment of the present disclosure.

### DETAILED DESCRIPTION OF PREFERRED EMBODIMENTS

The technical solutions of the embodiments of the present disclosure are clearly and completely described below with reference to the accompanying drawings of the embodiments of the present disclosure. Apparently, the described embodiments are merely some but not all of the embodiments of the present disclosure. All other embodiments obtained by a person skilled in the art based on the embodiments of the present disclosure without creative efforts shall fall within the protection scope of the present disclosure.

In the descriptions of the present disclosure, it should be understood that the directional or positional relationship indicated by the terms “on”, “away from”, “close to”, and the like are based on the directional or positional relationship shown in the drawings. For example, “on” indicates that a surface is above an object, specifically referring to directly above, obliquely above, or upper surface, as long as the surface is above the level of the object, and “close to” refers to a side closer to another object among the two sides of the object in the figure. The foregoing directional or positional relationship is only for convenience of describing the present disclosure and simplifying description, but does not indicate or imply that the mentioned apparatus or element needs to have a particular direction and be constructed and operated in the particular direction, and therefore cannot be understood as a limitation on the present disclosure.

In addition, it should be noted that the drawings provide only the structures closely related to the present disclosure, and omit some details that are not relevant to the present disclosure. The purpose is to simplify the drawings so that the points of the present disclosure are clear at a glance, rather than showing that an actual apparatus is exactly the same as the drawings, and the actual apparatus is not limited thereto.

The present disclosure provides a display panel that includes but is not limited to the following embodiments.

In an embodiment, as shown in FIGS. 1 to 3, the display panel 100 includes: a substrate 10; a light-emitting layer located on the substrate 10, wherein the light-emitting layer 20 includes a plurality of light-emitting parts 201, and at least one of the light-emitting parts 201 is the first type of light-emitting part 2011; and a color resistance layer located on a side of the light-emitting layer away from the substrate 10, the color resistance layer including a plurality of color resistance parts 301 corresponding to a plurality of the light-emitting parts 201 on a one-to-one correspondence, each of the color resistance parts 301 being arranged opposite to a corresponding light-emitting part 201, and at least one of the color resistance parts 301 being the first type color resistance part 3011 arranged opposite to the first type of light-emitting part 2011; wherein the first type of color resistance part 3011 includes a shielding part 401 that is configured to block light from passing through.

Wherein, the substrate 10 may be a flexible substrate whose constituent material may include but be not limited to polyimide or a rigid substrate whose constituent material may include but be not limited to glass. Wherein, a plurality of light-emitting parts 201 may include but are not limited to red light-emitting parts which emit red light, green light-emitting parts which emit green light and blue light-emitting parts which emit blue light, and the constituent materials of the light-emitting parts 201 which emit different colors may be different; furthermore, a pixel definition part 501 may be provided between two adjacent light-emitting parts 201, and the pixel definition part 501 is configured to block the two adjacent light-emitting parts 201 so as to avoid color mixing between the two; furthermore, a plurality of pixel definition parts 501 may be formed before a plurality of light-emitting parts 201, and an angle between a side portion and a bottom portion of the pixel definition parts 501 may be an acute angle, so that the light-emitting parts 201 are filled between the corresponding two pixel definition parts 501 and the risk of overflowing of the light-emitting parts 201 is reduced.

Specifically, the wavelength range of the light that can be transmitted by the color resistance part 301 corresponding to the red light-emitting part includes the wavelength of the red light, the wavelength range of the light that can be transmitted by the color resistance part 301 corresponding to the green light-emitting part includes the wavelength of the green light, and the wavelength range of the light that can be transmitted by the color resistance part 301 corresponding to the blue light-emitting part includes the wavelength of the blue light, that is, the wavelength range of the light that can be transmitted by each color resistance part 301 includes the wavelength of the light emitted by the corresponding light-emitting part 201. In addition, the wavelength of light emitted by each light-emitting part 201 is outside the wavelength range of light that can be transmitted by the color resistance part 301 corresponding to the light-emitting part 201 emitting light of a different color, so as to avoid color mixing when displaying a picture.

In particular, the first type of light-emitting part 2011 can be understood as a light-emitting part 201 which emits light abnormally. For example, the luminance difference between the light actually emitted by the first type of light-emitting part 2011 and the light theoretically emitted is large; the first type of light-emitting part 2011 cannot be turned off; the first type of light-emitting part 2011 which emits light abnormally in a partial region in the region where the first type of light-emitting part 2011 is located where the luminance is abnormal due to the action of foreign matter. It should be noted that since the human eye has a high sensitivity to bright spots, if the region where the first type of light-emitting part 2011 is located is not disposed, the picture display quality of the display panel 100 may be seriously degraded.

Specifically, in the present embodiment, a shielding part 401 is provided in the first type of color resistance part 3011 which is provided opposite to the first type of light-emitting part 2011, and the shielding part 401 is configured to block light from passing through, namely, light emitted by the first type of light-emitting part 2011 can be blocked by the corresponding shielding part 401 so as to avoid being incident on a human eye, namely, the region where the first type of light-emitting part 2011 is located appears in a normally dark state. It can be understood that since the human eye has a low sensitivity to a dark point, and when the display panel 100 performs picture display, the number of the first type of light-emitting parts 2011 in a dark state is very small, the light emitted by the other light-emitting parts 201 meets the requirements so as to enable a corresponding region to be displayed normally, namely, the dark point in a picture received by the human eye can be ignored, and the picture display quality of the display panel 100 is improved.

It should be noted that when a laser acts on the conductive material located below the color resistance layer, since part of the color resistance part 301 cannot be passed through by the laser, the conductive material in the corresponding region cannot be removed, so that the corresponding light-emitting part 201 cannot be prevented from emitting light, and thus a bright spot still exists. In conjunction with the above discussion, in the present embodiment, by providing the shielding part 401 in the first type of color resistance part 3011 arranged opposite to the first type of light-emitting part 2011 so as to block the light emitted by the first type of light-emitting part 2011 from passing through, namely, the shielding part 401 in the present embodiment is not located on a side of the first type of color resistance part 3011 close to the light-emitting layer, avoiding using a laser to eliminate bright spots by penetrating the color resistance part 301, and improving the success rate of pixel repair.

In an embodiment, as shown in FIGS. 1 to 3, the shielding part 401 is located in a corresponding region of the first type of color resistance part 3011 away from the light-emitting layer. As can be understood, in the first type of color resistance part 3011 of the present embodiment, the shielding part 401 is provided close to the light-emitting side of the display panel 100, so that the elimination of light can be performed in a region close to the light-emitting side, and the need for secondary elimination of light due to the shielding part 401 being provided at a relatively long distance from the light-emitting side is avoided, thereby improving the reliability of light elimination. Specifically, laser light may be configured to irradiate the first type of color resistance part 3011 from the light-emitting side of the display panel 100 to act on the first type of color resistance part 3011 near the light-emitting side of the display panel 100 to convert the first type of color resistance part 3011 near the light-emitting side of the display panel 100 into the shielding part 401.

In an embodiment, the constituent material of the shielding part 401 includes carbon. Wherein, the constituent material of the color resistance part 301 can be an organic material, namely, the constituent material of the color resistance part 301 can include carbon, oxygen- and hydrogen; in conjunction with the above-mentioned discussion, laser light is configured to irradiate the first type of color resistance part 3011 from the light-emitting side of the display panel 100, so that the part of the first type of color resistance part 3011 close to the light-emitting side of the display panel 100 can have a carbonization effect, and it can be understood that the oxygen and the hydrogen in the part of the first type of color resistance part 3011 close to the light-emitting side of the display panel 100 become gaseous and leave the first type of color resistance part 3011; so that the part of the first type of color resistance part 3011 close to the light-emitting side of the display panel 100 only includes carbon formed as a shielding part 401, and it can be understood that the shielding part 401 includes a plurality of particles formed by carbon in black; therefore, the shielding part 401 can block light emitted by the first type of light-emitting part 2011 from passing through so as to make a corresponding region appear in a dark state, thereby achieving the repair of a corresponding sub-pixel.

In an embodiment, as shown in FIGS. 1 to 3, the display panel 100 further includes: a black matrix layer arranged on the same layer as the color resistance layer, wherein, the black matrix layer includes a plurality of black matrix parts 601, an included angle between a side portion and a bottom portion of the black matrix parts 601 is an acute angle, and a color resistance part 301 is filled between two adjacent black matrix parts 601; as shown in FIG. 1, each side portion of the shielding part 401 is coplanar with an adjacent side portion of the adjacent black matrix part 601.

It should be noted that, as shown in FIGS. 1 to 3, the angle between the side portion and the bottom portion of the black matrix part 601 is an acute angle, and in conjunction with the above discussion regarding the pixel definition part 501, the black matrix part 601 can block two adjacent color resistance parts 301 to avoid color mixing. In conjunction with the discussion above, the wavelength range of the light that can be transmitted by each color resistance part 301 includes the wavelength of the light emitted by the corresponding light-emitting part 201, and the wavelength of the light emitted by each light-emitting part 201 is outside the wavelength range of the light that can be transmitted by the color resistance part 301 corresponding to the light-emitting part 201 emitting light of different colors; the black matrix part 601 in the present embodiment is located between two adjacent color resistance parts 301; and the black matrix part 601 can absorb light of any color, namely, the region where a plurality of color resistance parts 301 are located is a light-transmitting region. Light rays of a corresponding color can be transmitted; furthermore, the included angle between the side portion of the black matrix part 601 and the bottom portion is an acute angle, namely, the corresponding light-transmitting region also exhibits a gradually increasing opening, effectively increasing the light-emitting region.

On this basis, as shown in FIG. 1, each side portion of the shielding part 401 in the present embodiment is coplanar with an adjacent side portion of the adjacent black matrix part 601, that is to say, the shielding part 401 may be formed as a side of the corresponding first type of color resistance part 3011 away from the light-emitting layer, and may also block light emitted through the side portion of the first type of color resistance part 3011; as can be appreciated, when the first type of light-emitting part 2011 emits light abnormally as a whole, the present embodiment can achieve the overall blocking of light emitted from the first type of light-emitting part 2011, improving the reliability of the repair of the corresponding sub-pixel.

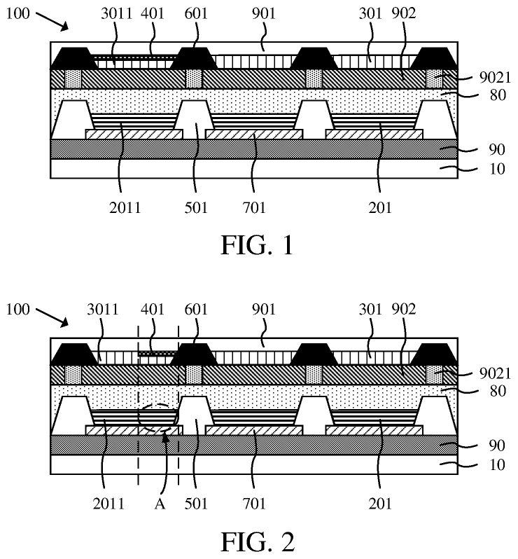

In an embodiment, as shown in FIG. 2, the first type of light-emitting part 2011 includes an abnormal region A, and the shielding part 401 is arranged opposite to the abnormal region A in the corresponding the first type of light-emitting part 2011. Wherein, in conjunction with the above discussion, the abnormal region A can be understood to be a partial region in the region where the first type of light-emitting part 2011 is located where the luminance is abnormal due to the action of foreign matter, i.e. a region other than the abnormal region A in the first type of light-emitting part 2011 can emit light normally. It can be understood that the shielding part 401 in the present embodiment is provided only opposite to the abnormal region A in the corresponding first type of light-emitting part 2011, and is not provided opposite to the entire first type of light-emitting part 2011. On the one hand, light emitted from a portion of the first type of light-emitting part 2011 excluding the abnormal region A can still be emitted through a portion of the first type of color resistance part 3011 excluding the shielding part 401 to reduce the size of a dark spot. On the other hand, in conjunction with the above discussion, only the part of the first type of color resistance part 3011 which is arranged opposite to the abnormal region A in the corresponding first type of light-emitting part 2011 can be carbonized, so that the range of laser action is reduced, and the pixel repair efficiency can be effectively saved or improved.

In an embodiment, as shown in FIGS. 1 to 3, the display panel 100 further includes: an anode layer located on a side of the light-emitting layer close to the substrate 10, the anode layer including a plurality of anode parts 701 corresponding to a plurality of the light-emitting parts 201 on a one-to-one correspondence; a cathode layer 80 located on the side of the light-emitting layer away from the substrate 10, and as shown in FIGS. 1 and 2, the cathode layer 80 covers at least a side of the first type of light-emitting part 2011 away from the substrate 10.

Wherein, each anode part 701 may have a corresponding anode voltage, and the whole layer of cathode layers 80 may have a cathode voltage; with regard to the light-emitting part 201 located between the anode part 701 and the cathode layer 80, under the action of the corresponding anode voltage and cathode voltage, electrons are injected from the cathode layer 80 into the light-emitting part 201, while holes are injected from the anode part 701 into the light-emitting part 201, so that electrons and holes are recombined in the light-emitting part 201 to emit light. Furthermore, as shown in FIGS. 1 to 3, the display panel 100 also includes a circuit layer 90 located between the substrate 10 and the anode layer, wherein the circuit layer 90 may include a plurality of gate lines transmitting gate signals, a plurality of data lines transmitting data signals and a plurality of driving transistors, a plurality of thin film transistors and a plurality of light-emitting parts 201 that are corresponding one-to-one, and each thin film transistor is arranged opposite to the corresponding light-emitting part 201 and is electrically connected to the corresponding anode part 701; a plurality of gate lines and a plurality of data lines are arranged to intersect to form a plurality of unit regions, and each driving transistor is located in the corresponding unit region; specifically, each thin film transistor is electrically connected to a corresponding gate line and a corresponding data line to input a corresponding signal to a corresponding anode part 701, thereby controlling a corresponding light-emitting part 201 to emit light.

It can be understood that due to the uncertainty of the light-emitting part 201 with abnormal light emission, a whole layer of the cathode layer 80 can be formed before pixel repair is performed; in conjunction with the above discussion, in the present disclosure, the corresponding first type of color resistance part 3011 is further disposed according to the position of the first type of light-emitting part 2011 to form the shielding part 401 so as to block the light emitted by the first type of light-emitting part 2011 from emitting the light-emitting side; on this basis, in the present embodiment, it is defined that the cathode layer 80 covers at least one side of the first type of light-emitting part 2011 away from the substrate 10; that is, the present embodiment prevents the first type of light-emitting part 2011 from emitting light without disposing the portion of the cathode layer 80 disposed opposite to the first type of light-emitting part 2011. Therefore, on the one hand, the present embodiment avoids removing the part of the cathode layer 80 corresponding to the first type of light-emitting part 2011, and in conjunction with the above discussion, the present embodiment can reduce the risk that the bright spot cannot be removed because the laser light cannot penetrate some of the light-emitting parts 201 and act on the corresponding part of the cathode layer 80, thereby improving the success rate of pixel repair; on the other hand, when only a portion of the first type of color resistance part 3011 disposed opposite to the abnormal region A in the corresponding first type of light-emitting part 2011 is carbonized, since the cathode layer 80 covers the side of the first type of light-emitting part 2011 away from the substrate 10, the first type of light-emitting part 2011 can still emit light, and light emitted from a portion of the first type of light-emitting part 2011 excluding the abnormal region A can still be emitted through a portion of the first type of color resistance part 3011 excluding the shielding part 401 to reduce the size of the dark spot.

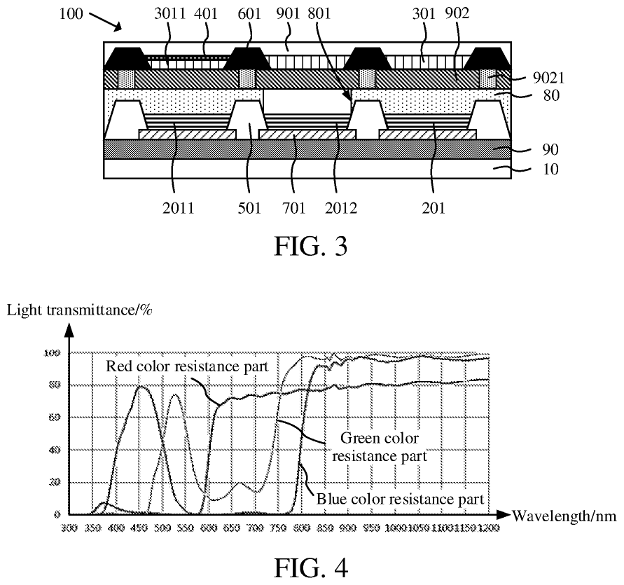

In an embodiment, as shown in FIG. 3, at least one of the light-emitting parts 201 is the second light-emitting part 2012, and the cathode layer 80 is provided with at least one opening 801, wherein the opening 801 and the second type of light-emitting part 2012 are oppositely arranged. The second type of light-emitting part 2012 can also be understood as a light-emitting part 201 which emits light abnormally, and reference can be made to the relevant description above regarding the first type of light-emitting part 2011, and the light-emitting color of the second type of light-emitting part 2012 and the light-emitting color of the first type of light-emitting part 2011 can be the same or different.

As can be understood, there is a difference in the transmittance distribution of the color resistance part 301 corresponding to the light-emitting parts 201 of different colors for light. Here, the transmittance distribution of the red color resistance part corresponding to the red light-emitting part, the green color resistance part corresponding to the green light-emitting part, and the blue color resistance part corresponding to the blue light-emitting part for light is illustrated as shown in FIG. 4. The transmittance of the red color resistance part for light with a wavelength greater than 650 nm may be approximately 70% or more, and the transmittance of the green color resistance part for light with a wavelength of 500 nm to 570 nm and light with a wavelength greater than 750 nm may be approximately 40% or more, and the transmittance of the blue color resistance part for light with a wavelength of 420 nm to 500 nm and light with a wavelength greater than 850 nm may be approximately 40% or more.

Specifically, in conjunction with FIGS. 3 and 4, when the first type of color resistance part 3011 is any one of a red color resistance part, a green color resistance part and a blue color resistance part, since the light transmittance of any one of the red color resistance part, the green color resistance part and the blue color resistance part for light with a wavelength of less than 350 nm is all extremely low, namely, corresponding to that the absorption is all extremely high, it can be understood that light with a wavelength of less than 350 nm can sufficiently act on any one of the red color resistance part, the green color resistance part and the blue color resistance part so as to generate a carbonization effect; therefore, each of the first type of color resistance parts 3011 can be disposed with a laser having a wavelength of less than 350 nm to form the shielding part 401.

Wherein, as shown in FIGS. 1 to 3, the display panel 100 may further include a planarization layer 901 on a side of the color resistance layer and the black matrix layer away from the substrate 10, and a side of the planarization layer 901 away from the substrate 10 may be parallel to a horizontal plane to realize planarization. The second type of light-emitting part 2012 in the present embodiment can be understood as avoiding light emission of the second type of light-emitting part 2012 by removing the corresponding cathode.

Specifically, in conjunction with FIGS. 3 and 4, in order to avoid that a film layer such as a flat layer 901 located on the color resistance layer will be damaged due to the excessive penetration rate of the laser light, when the second type of light-emitting part 2012 is a red light-emitting part, the color resistance part 301 corresponding to the second type of light-emitting part 2012 can be penetrated by the laser light with a wavelength of 650 nm to 750 nm, namely, the cathode layer 80 is disposed by penetrating the red color resistance part by the laser light with a wavelength of 650 nm to 750 nm to form a corresponding opening 801; when the second type of light-emitting part 2012 is a green light-emitting part, the color resistance part 301 corresponding to the second type of light-emitting part 2012 can be penetrated by a laser with a wavelength of 520 nm to 550 nm, namely, the cathode layer 80 can be disposed by penetrating the green color resistance part with a laser with a wavelength of 520 nm to 550 nm to form a corresponding opening 801; when the second type of light-emitting part 2012 is a blue light-emitting part, the color resistance part 301 corresponding to the second type of light-emitting part 2012 can be penetrated by a laser with a wavelength of 420 nm to 490 nm; that is, the cathode layer 80 is disposed with, but not limited to, laser light having a wavelength of 420 nm to 490 nm through the blue color resistance part to form a corresponding opening 801.

In an embodiment, as shown in FIG. 4, a plurality of color resistance parts corresponding to a plurality of the light-emitting parts having different light-emitting colors on a one-to-one correspondence have a transmittance of more than 60% for light having a wavelength of more than 850 nm. Specifically, in conjunction with FIG. 4 and the above description, it can be seen that the transmittance of the red color resistance part for light with a wavelength greater than 650 nm can be approximately 70% or above, the transmittance of the green color resistance part for light with a wavelength greater than 750 nm can be approximately 40% or above, and the transmittance of the blue color resistance part for light with a wavelength greater than 850 nm can be approximately 40% or above. On this basis, as shown in FIG. 4, the transmittance of the red color resistance part, the green color resistance part and the blue color resistance part in the present embodiment for light with a wavelength greater than 850 nm can all be greater than 60%. Therefore, under the premise of ensuring that a film layer such as the flat layer 901 on the color resistance layer is not burned, a laser with a wavelength greater than 850 nm may be configured to penetrate a corresponding region of the red color resistance part, the green color resistance part or the blue color resistance part in the cathode layer 80 to form a corresponding opening 801.

In an embodiment, as shown in FIGS. 1 to 3, the display panel 100 further includes: a touch control layer 902 located on a side of the color resistance layer close to the light-emitting layer, wherein the touch control layer 902 includes a plurality of touch control electrodes 9021, and the touch control electrodes 9021 are located between the two adjacent light-emitting parts 201. The touch control layer 902 can realize a touch control function, and a plurality of touch control electrodes 9021 can include a plurality of transmitting electrodes and a plurality of receiving electrodes, wherein the transmitting electrodes can transmit a touch control transmitting signal to drive the receiving electrodes to work, and the receiving electrodes can generate a touch control sensing signal under an external touch. It can be understood that the touch control layer 902 in the present embodiment can be a capacitive touch control layer rather than an optical touch control layer so as to avoid being affected by the shielding part 401; furthermore, the touch control electrode 9021 is located between two adjacent light-emitting parts 201, and the influence of the touch control layer 902 on the light emitted by the light-emitting parts 201 can be reduced. Further, the constituent material of the touch control electrode 9021 may include indium tin oxide to further reduce the influence of the touch control layer 902 on light emitted from the light-emitting part 201.

The present disclosure also provides a mobile terminal including a terminal main body part and a display panel as recited in any of the above, the terminal main body part and the display panel being integrated.

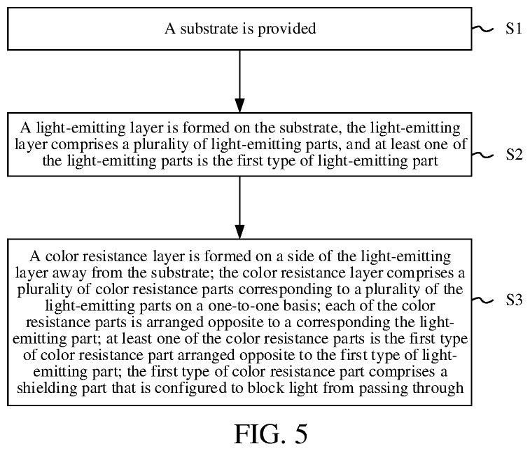

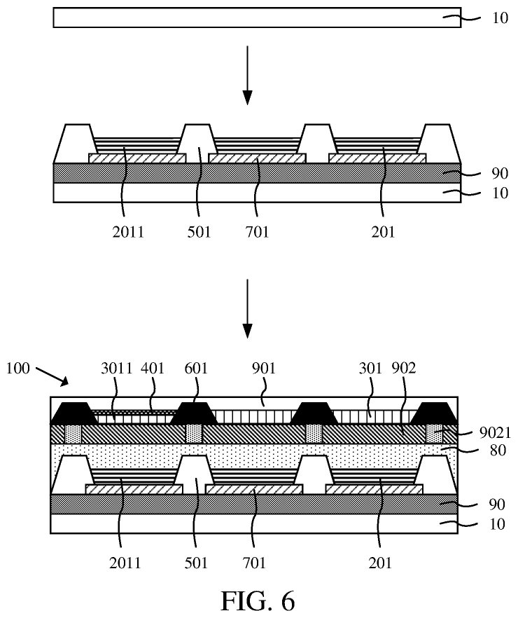

The present disclosure also provides a method of manufacturing of the display panel, as shown in FIG. 5, which may include but be not limited to the following steps, and is referred to in conjunction with the schematic diagram of scenario of FIG. 6.

S1, a substrate is provided.

Wherein, as shown in FIG. 6, the substrate 10 may be a flexible substrate whose constituent material may include but be not limited to polyimide or a rigid substrate whose constituent material may include but be not limited to glass.

S2, a light-emitting layer is formed on the substrate, wherein the light-emitting layer includes a plurality of light-emitting parts, and at least one of the light-emitting parts is the first type of light-emitting part;

Wherein, as shown in FIG. 6, a plurality of the light-emitting parts 201 can include but be not limited to red light-emitting parts which emit red light, green light-emitting parts which emit green light and blue light-emitting parts which emit blue light, and the constituent materials of the light-emitting parts with different light-emitting colors can be different; furthermore, a pixel definition part 501 may be provided between two adjacent light-emitting parts 201, and the pixel definition part 501 is configured to block the two adjacent light-emitting parts 201 so as to avoid color mixing between the two; further, a plurality of pixel definition parts 501 may be formed before a plurality of light-emitting parts 201, and an angle between a side portion and a bottom portion of the pixel definition parts 501 may be an acute angle, so that the light-emitting parts 201 are filled between the corresponding two pixel definition parts 501 and the risk of overflowing of the light-emitting parts 201 is reduced.

In particular, the first type of light-emitting part 2011 can be understood as a light-emitting part that emits light abnormally. For example, the luminance difference between the light actually emitted by the first type of light-emitting part 2011 and the light theoretically emitted is large; the first type of light-emitting part 2011 cannot be turned off; the first type of light-emitting part 2011 which emits light abnormally in a partial region in the region where the first type of light-emitting part 2011 is located where the luminance is abnormal due to the action of foreign matter. It should be noted that since the human eye has a high sensitivity to bright spots, if the region where the first type of light-emitting part 2011 is located is not disposed, the picture display quality of the display panel may be seriously degraded.

Specifically, as shown in FIG. 6, before forming a plurality of pixel definition parts 501, a wiring layer 90, a plurality of anode parts 701 located on the wiring layer 90 may be sequentially formed on the substrate 10, and a specific arrangement of the wiring layer 90 and a plurality of anode parts 701 may refer to the relevant description above.

S3, a color resistance layer is formed on a side of the light-emitting layer away from the substrate; the color resistance layer includes a plurality of color resistance parts corresponding to a plurality of the light-emitting parts on a one-to-one correspondence; each of the color resistance parts is arranged opposite to a corresponding the light-emitting part; at least one of the color resistance parts is the first type of color resistance part arranged opposite to the first type of light-emitting part; the first type of color resistance part includes a shielding part that is configured to block light from passing through.

Specifically, as shown in FIG. 6, the wavelength range of the light that can be transmitted by each color resistance part 301 includes the wavelength of the light emitted by the corresponding light-emitting part 201, and the wavelength of the light emitted by each light-emitting part 201 is outside the wavelength range of the light that can be transmitted by the color resistance part 301 corresponding to the light-emitting part 201 that emits light of a different color, so as to avoid color mixing when displaying a picture.

It can be understood that in the present embodiment, a shielding part 401 is provided in the first type of color resistance part 3011 which is provided opposite to the first type of light-emitting part 2011, and the shielding part 401 is configured to block light from passing through, namely, light emitted by the first type of light-emitting part 2011 can be blocked by the corresponding shielding part 401 so as to avoid being incident on a human eye, namely, the region where the first type of light-emitting part 2011 is located appears in a normally dark state. It can be understood that since the human eye has a low sensitivity to a dark point, and when a display panel displays a picture, the number of the first type of light-emitting parts 2011 in a dark state is very small, the light emitted by the other light-emitting parts 201 meets the requirements so as to enable a corresponding region to display normally, namely, the dark point in the picture received by the human eye can be ignored, and the picture display quality of the display panel is improved. Furthermore, in the present embodiment, by providing the shielding part 401 in the first type of color resistance part 3011 arranged opposite to the first type of light-emitting part 2011 so as to block light emitted from the first type of light-emitting part 2011 from passing through, it is possible to avoid using a laser to pass through the color resistance part 301 so as to eliminate bright spots, thereby improving the success rate of pixel repair.

Specifically, as shown in FIG. 6, before the color resistance layer is formed, a cathode layer 80, a touch control layer 902 located on the cathode layer 80, and a plurality of black matrix parts 601 located on the touch control layer 902 can be formed successively on the light-emitting layer; the touch control layer 902 includes a plurality of touch control electrodes 9021; after the color resistance layer is formed, a flat layer 901 can be formed on the color resistance layer and a plurality of black matrix parts 601; and the specific arrangement of the cathode layer 80, the touch control layer 902, the black matrix parts 601 and the touch control electrodes 9021 can be described with reference to the relevant description above.

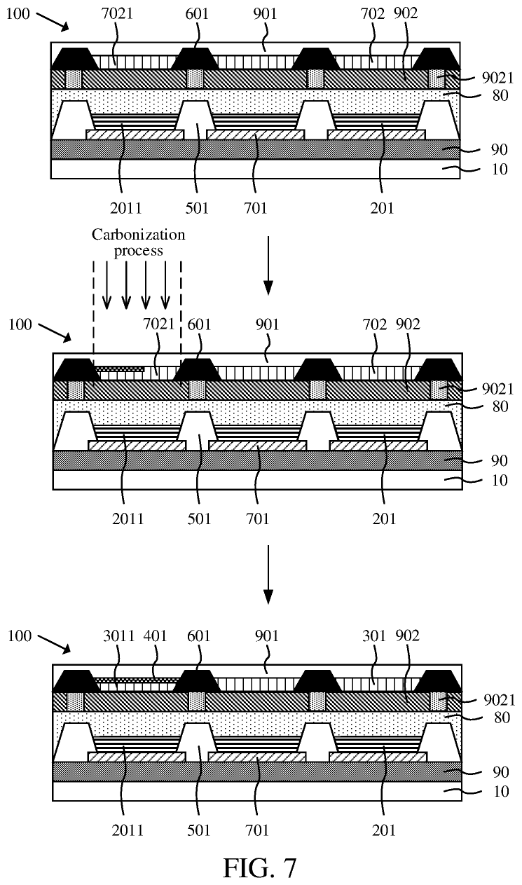

The step of forming the first type of color resistance part in step S3 may include but be not limited to the following steps, and reference is made to the schematic diagram of scenario of FIG. 7.

S301, the first type of color resistance block is formed on a side of the first type of light-emitting part away from the substrate.

Specifically, as shown in FIG. 7, it can be understood here that a plurality of color resistance blocks 702 are formed on the side of the first type of light-emitting part 2011 away from the substrate 10, and a plurality of color resistance blocks 702 are configured to form a plurality of color resistance parts 301, wherein a plurality of color resistance blocks 702 are also configured to form a color resistance block including a shielding part 401, which is referred to as the first type of color resistance block 7021, namely, the constituent material of each color resistance block 702 can be the same as the constituent material of the corresponding color resistance part 301 except for the shielding part 401.

S302, the first type of color resistance block is processed by a laser from a side of the first type of color resistance block away from the substrate to form the shielding part in the first type of color resistance block.

Specifically, as shown in FIG. 7, a laser may be configured to irradiate the side of the first type of color resistance block 7021 remote from the substrate 10 to perform the charring process, wherein the selection of the laser for performing the charring process may be as described above in connection with FIG. 4. Specifically, the laser energy, the irradiation time and the irradiation region can be selected according to the actual situation, and it is necessary to avoid burning the film layer such as the flat layer 901 on the color resistance layer.

Wherein, in conjunction with the discussion above, the first type color resistance block 7021 may form the first type of color resistance part 3011 including the shielding part 401 via a carbonization process, and a plurality of color resistance blocks 702 not subjected to the carbonization process remain as a plurality of color resistance parts 301. Of course, in conjunction with the discussion above, the charring process may be performed after forming the planarization layer 901.

The present disclosure provides a display panel, a method for manufacturing thereof, and a mobile terminal, wherein the display panel includes: a substrate; a light-emitting layer located on the substrate, wherein the light-emitting layer includes a plurality of light-emitting parts, and at least one of the light-emitting parts is the first type of light-emitting part; and a color resistance layer located on a side of the light-emitting layer away from the substrate, the color resistance layer including a plurality of color resistance parts corresponding to a plurality of the light-emitting parts on a one-to-one correspondence, each of the color resistance parts being arranged opposite to a corresponding light-emitting part, and at least one of the color resistance parts being the first type of color resistance part arranged opposite to a first type of light-emitting part; wherein the first type of color resistance part includes a shielding part that is configured to block light from passing through. Wherein, the present disclosure improves the success rate of pixel repair by providing the first type of color resistance part to include a shielding part for blocking light from passing through, so as to realize the function of blocking light emitted by the first type of color resistance part from passing through, avoiding the use of a laser to eliminate bright spots by penetrating through the color resistance part.

The display panel, the structure of the mobile terminal and the manufacturing method of the display panel provided by the embodiments of the present disclosure have been described in detail above. The principle and implementations of the present disclosure are described herein through specific examples. The description about the embodiments of the present disclosure is merely provided to help understand the technical solutions and core ideas of the present disclosure. A person of ordinary skill in the art should understand that, modifications may still be made to the technical solutions in the foregoing embodiments, or equivalent replacements may be made to some of the technical features; and such modifications or replacements will not cause the essence of corresponding technical solutions to depart from the scope of the technical solutions in the embodiments of the present disclosure.

What is claimed is:

1. A display panel comprising:
a substrate;
a light-emitting layer located on the substrate, wherein the light-emitting layer comprises a plurality of light-emitting parts, and at least one of the light-emitting parts is a first type of light-emitting part; and
a color resistance layer located on a side of the light-emitting layer away from the substrate, wherein the color resistance layer comprises a plurality of color resistance parts corresponding to a plurality of the light-emitting parts on a one-to-one correspondence, each of the color resistance parts is arranged opposite to a corresponding light-emitting part, and at least one of the color resistance parts is a first type of color resistance part arranged opposite to the first type of light-emitting part;
wherein the first type of color resistance part comprises a shielding part that is configured to block light from passing through.

2. The display panel as claimed in claim 1, wherein the shielding part is located in a region where a corresponding first type of color resistance part is away from the light-emitting layer.

3. The display panel as claimed in claim 1, wherein a constituent material of the shielding part comprises carbon.

4. The display panel as claimed in claim 1, further comprising:
a black matrix layer arranged on the same layer as the color resistance layer, wherein the black matrix layer comprises a plurality of black matrix parts, an included angle between a side portion and a bottom portion of the black matrix part is an acute angle, and a color resistance part is filled between two adjacent black matrix parts;
wherein each side portion of the shielding part is coplanar with an adjacent side portion of an adjacent color resistance part.

5. The display panel as claimed in claim 1, wherein the first type of light-emitting part comprises an abnormal region, and the shielding part is disposed opposite to the abnormal region in the corresponding first type of light-emitting part.

6. The display panel as claimed in claim 1, further comprising:
an anode layer located on a side of the light-emitting layer close to the substrate, wherein the anode layer comprises a plurality of anode parts corresponding to a plurality of light-emitting parts on a one-to-one correspondence;
a cathode layer located on a side of the light-emitting layer away from the substrate, wherein the cathode layer covers at least a side of the first type of light-emitting part away from the substrate.

7. The display panel as claimed in claim 6, wherein at least one of the light-emitting parts is a second type of light-emitting part, and the cathode layer is provided with at least one of openings disposed opposite to the second type of light-emitting part.

8. The display panel as claimed in claim 1, wherein a plurality of the color resistance parts corresponding to a plurality of light-emitting parts different in light-emitting colors on a one-to-one correspondence have a transmittance of more than 60% for light having a wavelength of more than 850 nm.

9. The display panel as claimed in claim 1, further comprising:
a touch control layer located on a side of the color resistance layer close to the light-emitting layer, wherein the touch control layer comprises a plurality of touch control electrodes, and the touch control electrodes are located between two adjacent light-emitting parts.

10. A mobile terminal comprising a terminal main body part and the display panel according to claim 1, wherein the terminal main body part and the display panel are integrated.

11. The mobile terminal as claimed in claim 10, wherein the shielding part is located in a region where a corresponding first type of color resistance part is away from the light-emitting layer.

12. The mobile terminal as claimed in claim 10, wherein a constituent material of the shielding part comprises carbon.

13. The mobile terminal as claimed in claim 10, further comprising:
a black matrix layer arranged on the same layer as the color resistance layer, wherein the black matrix layer comprises a plurality of black matrix parts, an included angle between a side portion and a bottom portion of the black matrix part is an acute angle, and a color resistance part is filled between two adjacent black matrix parts;
wherein each side portion of the shielding part is coplanar with an adjacent side portion of an adjacent color resistance part.

14. The mobile terminal as claimed in claim 10, wherein the first type of light-emitting part comprises an abnormal region, and the shielding part is disposed opposite to the abnormal region in the corresponding first type of light-emitting part.

15. The mobile terminal as claimed in claim 10, further comprising:
an anode layer located on a side of the light-emitting layer close to the substrate, wherein the anode layer comprises a plurality of anode parts corresponding to a plurality of light-emitting parts on a one-to-one correspondence;
a cathode layer located on a side of the light-emitting layer away from the substrate, wherein the cathode layer covers at least a side of the first type of light-emitting part away from the substrate.

16. The mobile terminal as claimed in claim 15, wherein at least one of the light-emitting parts is a second type of light-emitting part, and the cathode layer is provided with at least one of openings disposed opposite to the second type of light-emitting part.

17. The mobile terminal as claimed in claim 10, wherein a plurality of the color resistance parts corresponding to a plurality of light-emitting parts different in light-emitting colors on a one-to-one correspondence have a transmittance of more than 60% for light having a wavelength of more than 850 nm.

18. The mobile terminal as claimed in claim 10, further comprising:
a touch control layer located on a side of the color resistance layer close to the light-emitting layer, wherein the touch control layer comprises a plurality of touch control electrodes, and the touch control electrodes are located between two adjacent light-emitting parts.

19. A method of manufacturing of a display panel comprising following steps:
providing a substrate;
forming a light-emitting layer on the substrate, wherein the light-emitting layer comprises a plurality of light-emitting parts, and at least one of the light-emitting parts is a first type of light-emitting part; and
forming a color resistance layer on a side of the light-emitting layer away from the substrate, wherein the color resistance layer comprises a plurality of color resistance parts corresponding to a plurality of the light-emitting parts on a one-to-one correspondence, each of the color resistance parts is arranged opposite to a corresponding light-emitting part, at least one of the color resistance parts is a first type of color resistance part arranged opposite to the first type of light-emitting part, and the first type of color resistance part comprises a shielding part that is configured to block light from passing through;
wherein the step of forming the first type of color resistance part comprises:
forming a first type of color resistance block on a side of the first type of light-emitting part away from the substrate; and
processing the first type of color resistance block by a laser from a side of the first type of color resistance block away from the substrate to form the shielding part within the first type of color resistance block.

20. The method of manufacturing of a display panel as claimed in claim 19, wherein, before step of forming a color resistance layer on a side of the light-emitting layer away from the substrate, the method comprises following steps:
forming a cathode layer, a touch control layer located on the cathode layer, and a plurality of black matrix parts located on the touch control layer successively, and the touch control layer comprising a plurality of touch control electrodes; wherein,
after step of forming a color resistance layer on a side of the light-emitting layer away from the substrate, the method comprises:
forming a planarization layer on a side of the color resistance layer and the plurality of black matrix parts away from the substrate.
